(19) United States
(12) Patent Application Publication
(10) Pub. No.: US 2025/0349647 A1
(43) Pub. Date: Nov. 13, 2025

(54) Thermal Resistance Extraction for Semiconductor Devices

(71) Applicant: INTERNATIONAL BUSINESS MACHINES CORPORATION, ARMONK, NY (US)

(72) Inventors: MIAOMIAO WANG, Albany, NY (US); Haojun Zhang, Schenectady, NY (US); Baozhen Li, South Burlington, VT (US); Craig Michael Child, Gansevoort, NY (US); HUIMEI ZHOU, ALBANY, NY (US); Huai Huang, Clifton Park, NY (US); Yuncheng Song, Halfmoon, NY (US); Dureseti Chidambarrao, Weston, CT (US); John Knickerbocker, Monroe, NY (US)

(21) Appl. No.: 18/658,957

(22) Filed: May 8, 2024

(51) Int. Cl. H01L 23/34; G01N 25/18

(52) U.S. Cl. CPC H01L 23/34; G01N 25/18

(57) ABSTRACT

A structure for extracting thermal resistance in semiconductor device includes first and second sensor arrays. Each sensor array of the first and second sensor arrays includes a heater; a first temperature sensor configured to measure temperature of the heater; and second and third temperature sensors on opposite sides of the heater. The heater and the temperature sensors of the first sensor array are along a first thermal path to ambient. The heater and the temperature sensors of the second sensor array are along a second thermal path to ambient. The first thermal path to ambient has a measurably different thermal resistance than the second thermal path to ambient.

### BACKGROUND

### Technical Field

The present disclosure generally relates to semiconductor devices, and more particularly, to thermal resistance extraction for semiconductor devices.

### Description of the Related Art

Temperature can significantly impact performance, reliability, and lifespan of semiconductor devices. Thermal design optimization is performed to ensure reliable and efficient operation.

Methods for thermal design optimization include thermal modeling. Simulation models may be used to evaluate thermal dissipation in semiconductor devices. Simulation models enable decisions to be made during semiconductor design to optimize heat transfer away from semiconductor components and other components.

Simulation models may incorporate thermal resistance, which may be used to predict and pre-determine potential hot spots and heat dissipation. Thermal resistance may be represented as the quotient of the temperature difference between two given points by the heat flow between the two points (amount of heat flow per unit time).

### SUMMARY

According to an embodiment of the present disclosure, a structure for extracting thermal resistance in semiconductor device includes first and second sensor arrays. Each sensor array of the first and second sensor arrays includes a heater; a first temperature sensor configured to measure temperature of the heater; and second and third temperature sensors on opposite sides of the heater. The heater and the temperature sensors of the first sensor array are along a first thermal path to ambient. The heater and the temperature sensors of the second sensor array are along a second thermal path to ambient. The first thermal path to ambient has a measurably different thermal resistance than the second thermal path to ambient.

In some embodiments, the semiconductor device has an interconnect, and the first, second and third temperature sensors of each sensor array are at first, second and third metal levels of the interconnect, respectively. For each sensor array, the first, second, and third temperature sensors are in substantial vertical alignment with the heater.

In some embodiments, the first sensor array includes a first dielectric region along the first thermal path to ambient, and the second sensor array includes a second dielectric region. along second first thermal path to ambient. The first dielectric region has a measurably different thermal resistance than the second dielectric region.

In some embodiments, thermal resistance between the first and second metal levels is the same for the first and second sensor arrays, and thermal resistance between the first and third metal levels is the same for the first and second sensor arrays.

In some embodiments, each sensor array further includes a fourth temperature sensor. Thermal resistance between the third and fourth temperature sensors is measurably different for the first and second sensor arrays.

In some embodiments, thermal resistance between the first and third metal levels is the same for the first and second sensor arrays, and thermal resistance between the first and second metal levels is measurably different for the first and second sensor arrays.

In some embodiments, the heater of each sensor array includes an electronic component between the first and third metal levels.

In some embodiments, the first, second and third temperature sensors of each sensor array include four-point Kelvin structures.

According to an embodiment of the present disclosure, a method of extracting thermal resistance in a semiconductor device includes applying equal heating power to spaced-apart first and second heaters at a first level of the semiconductor device. First and second sets of temperatures are measured. The thermal resistance is determined as a function of the heating power, and the first and second sets of temperatures. The first set includes a first temperature at the first heater, and second and third temperatures above and below the first heater at levels on opposite sides of the first level. The second set includes a first temperature at the second heater, and second and third temperatures above and below the second heater at the levels on opposite sides of the first level.

In some embodiments, heat generated by the first heater is flowed through a first dielectric region above or below the first heater. Heat generated by the second heater is flowed through a second dielectric region above or below the second heater. The first and second dielectric regions have measurably different thermal resistances.

In some embodiments, the thermal resistance is computed as a function of the heating power, a thermal dissipation ratio, temperature differences between the first and second levels, and temperature differences between the first and third levels.

In some embodiments, the thermal dissipation ratio (TDR) is computed as

$$TDR = \frac{( T 1 A - T 3 A ) - ( T 1 B - T 3 B )}{( T 1 B - T 2 B ) - ( T 1 A - T 2 A )}$$

where T1A, T2A and T3A are the first, second and third measured temperatures, respectively, of the first set; and T1B, T2B and T3B are the first, second and third measured temperatures, respectively, of the second set.

In some embodiments, the thermal resistance includes a thermal resistance (Rth_{1,2}) between the first and second levels and a thermal resistance (Rth_{1,3}) between the first and third levels, where

$$R t {h}_{1 , 2} = \frac{( T 1 A - T 2 A ) + ( T 1 A - T 3 A ) / TDR}{{Q}_{T o t a l}} and$$

$$Rt {h}_{1 , 3} = \frac{( T 1 A - T 3 A ) + ( T 1 A - T 2 A ) * T D R}{{Q}_{T o t a l}} .$$

According to an embodiment of the present disclosure, a semiconductor device includes an interconnect having a plurality of metal levels, and first and second sensor arrays. Each sensor array includes a heater at a first metal level of the plurality of metal levels. A first temperature sensor is at the first metal level and configured to measure temperature of the heater. Second and third temperature sensors are at second and third metal levels, respectively. The second and third metal levels are on opposite sides of the first metal level. The first, second, and third temperature sensors are in substantial vertical alignment with the heater.

In some embodiments, the semiconductor device includes a semiconductor substrate that is configured for back side power delivery. The first and second temperature sensors are on a front side of the semiconductor substrate. The third temperature sensor is on a back side of the semiconductor substrate.

In some embodiments, the semiconductor device includes a semiconductor substrate. The heater and the first, second and third temperature sensors of each sensor array are on one side of the semiconductor substrate.

In some embodiments, the semiconductor device further includes a processor programmed to compute thermal resistance between the second and third metal levels. As equal heating power is applied to the first and second heaters, a first set of temperatures is collected from the first, second and third temperature sensors of the first sensor array, a second set of temperatures is collected from the first, second and third temperature sensors of the second sensor array, and the thermal resistance is computed as a function of the heating power, and the first and second sets of temperatures.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1 is an illustration of a thermal resistance extraction structure, consistent with an illustrative embodiment.

FIG. 2 is a schematic representation of thermal paths for a sensor array in the thermal resistance extraction structure, consistent with an illustrative embodiment.

FIG. 3 is a flowchart of a method of extracting thermal resistance from a semiconductor device, consistent with an illustrative embodiment.

FIG. 4 is an illustration of a thermal resistance extraction structure, consistent with an illustrative embodiment.

FIG. 5 is an illustration of a thermal resistance extraction structure, consistent with an illustrative embodiment.

FIG. 6 is an illustration of a thermal resistance extraction structure, consistent with an illustrative embodiment.

FIG. 7 is an illustration of a semiconductor device configured for front side power delivery, consistent with an illustrative embodiment.

FIG. 8 is an illustration of a semiconductor device configured for back side power delivery, consistent with an illustrative embodiment.

FIG. 9 is an illustration of a thermal resistance extraction structure, consistent with an illustrative embodiment.

### DETAILED DESCRIPTION

### Definitions

Substrate: A substrate may refer to material that provides a support structure to features in or on top of the substrate material. As used below, there may be more than one substrate present in an embodiment shown. Also, since embodiments below are generally shown in cross-section, it should be understood that a substrate for a layer with patterned features may not be visible in the view so as to highlight the features for the layer.

Semiconductor substate: A semiconductor substrate may refer to any semiconductor-based substrate that has a semiconductor surface. The term “semiconductor” denotes any semiconducting material including, for example, Si, Ge, SiGe, SiC, SiGeC, and III-V compound semiconductors such as InAs, GaAs and InP.

Electrical components layer: An electrical components layer may refer to a region of a semiconductor device that includes electrical features for computing and processing signals. The layer may include active and/or passive components. The output from this layer may be provided to other parts of the overall device in some embodiments.

Active components: Active components may refer to electronic components that are parts of a circuit that rely on an external power source to control or modify electrical signals. Active components include for example, transistors, amplifiers, integrated circuits, diodes, photovoltaics, and rectifiers.

Passive components: Passive components may refer to devices that are incapable of controlling current by means of another electrical signal. Examples of passive components include resistors, inductors, capacitors, transformers, diodes and sensors.

Front End of Line (FEOL): The front end of line may refer to a layer of integrated circuit fabrication where individual components of an electrical components layer are formed in a semiconductor surface of a semiconductor substrate. In embodiments below, the FEOL may be shown placed on the “front side” of a semiconductor substrate.

Back End of Line (BEOL): The back end of line may refer to a layer of integrated circuit fabrication where the individual electronic components become interconnected with wiring on a substrate. In some embodiments below, the BEOL may be shown placed on the “front side” of an electrical components layer. In other embodiments below, the BEOL may be shown placed on the front side of an electrical components layer and also on a “back side” of a semiconductor substrate.

Interconnect: An interconnect may refer to one or more metal levels or layers configured to connect electrical components.

Dielectric: A dielectric is to be interpreted broadly and may include oxide materials such as SiO2, HfO2, ZrO2, HfSiO, HfZrO, and non-oxide materials such as SiN and AlN.

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a substrate.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

Accordingly, the teachings herein provide for experimental extraction of thermal resistance in a semiconductor device. As will be discussed below, the extraction may be performed between consecutive metal levels, but is not limited to consecutive metal levels. And, as will be discussed below, the thermal resistance extraction may be performed on semiconductor devices configured for front side power delivery, and it may also be performed on semiconductor devices configured for back side power delivery. Example implementations are provided below.

### Counterparting

According to various embodiments of the present disclosure, a structure for extracting thermal resistance in semiconductor device includes first and second sensor arrays. Each sensor array of the first and second sensor arrays includes a heater, a first temperature sensor configured to measure temperature of the heater, and second and third temperature sensors on opposite sides of the heater. The heater and the temperature sensors of the first sensor array are along a first thermal path to ambient. The heater and the temperature sensors of the second sensor array are along a second thermal path to ambient. The first thermal path to ambient has a measurably different thermal resistance than the second thermal path to ambient.

The structure enables thermal resistance to be measured rather than simulated. Measurements provide a more accurate evaluation of hot spots and thermal dissipation in a semiconductor device. The measurements may be used for thermal design optimization. The measurements may also be used for thermal calibration simulation.

In some embodiments, which can be combined with the preceding embodiment, the semiconductor device has an interconnect, and the first, second and third temperature sensors of each sensor array are at first, second and third metal levels of the interconnect, respectively. For each sensor array, the first, second, and third temperature sensors are in substantial vertical alignment with the heater.

In some embodiments, which can be combined with the preceding embodiments, the first sensor array includes a first dielectric region along the first thermal path to ambient, and the second sensor array includes a second dielectric region along the first thermal path to ambient. The first dielectric region has a measurably different thermal resistance than the second dielectric region. The measurable difference in thermal paths can be obtained simply by modifying one of the dielectric regions.

The structure is configurable as to the type of heater. In some embodiments, which can be combined with the preceding embodiments, the heater of each sensor array includes an electronic component between the first and second metal levels.

The structure is configurable as to the type of temperature sensor. In some embodiments, which can be combined with the preceding embodiments, the first, second and third temperature sensors of each sensor array include four-point Kelvin structures.

The structure is also highly configurable, as the locations of the heaters and thermal resistance differences in the first and second thermal paths. In one embodiment, thermal resistance between the first and second metal levels is the same for the first and second sensor arrays, and thermal resistance between the first and third metal levels is the same for the first and second sensor arrays. In another embodiment, each sensor array further includes a fourth temperature sensor. Thermal resistance between the third and fourth temperature sensors is measurably different for the first and second sensor arrays. In yet another embodiment, thermal resistance between the first and third metal levels is the same for the first and second sensor arrays, and thermal resistance between the first and second metal levels is measurably different for the first and second sensor arrays.

According to various embodiments of the present disclosure, a method of extracting thermal resistance in a semiconductor device includes applying equal heating power to spaced-apart first and second heaters at a first level of the semiconductor device, measuring first and second sets of temperatures, and determining the thermal resistance as a function of the heating power, and the first and second sets of temperatures. The first set includes a first temperature at the first heater, and second and third temperatures above and below the first heater at levels on opposite sides of the first level. The second set includes a first temperature at the second heater, and second and third temperatures above and below the second heater at the levels on opposite sides of the first level.

The method measures thermal resistance between levels as a function of the measured temperatures and the heating power. The measured thermal resistance can be used for thermal property monitoring and feedback for thermal design optimization.

In some embodiments, which can be combined with the preceding embodiment, heat generated by the first heater is flowed through a first dielectric region above or below the first heater; and heat generated by the second heater is flowed through a second dielectric region above or below the second heater. The first and second dielectric regions have measurably different thermal resistances.

In some embodiments, which can be combined with the preceding embodiments, the thermal resistance is computed as a function of the heating power, a thermal dissipation ratio, temperature differences between the first and second levels, and temperature differences between the first and third levels.

In some embodiments, which can be combined with the preceding embodiments, the thermal dissipation ratio (TDR) is computed as

$$TDR = \frac{( T 1 A - T 3 A ) - ( T 1 B - T 3 B )}{( T 1 B - T 2 B ) - ( T 1 A - T 2 A )}$$

where T1A, T2A and T3A are the first, second and third measured temperatures, respectively, of the first set; and T1B, T2B and T3B are the first, second and third measured temperatures, respectively, of the second set.

In some embodiments, which can be combined with the preceding embodiments, the thermal resistance includes a thermal resistance (Rth_{1,2}) between the first and second levels and a thermal resistance (Rth_{1,3}) between the first and third levels, where

$$Rt {h}_{1 , 2} = \frac{( T 1 A - T 2 A ) + ( T 1 A - T 3 A ) / TDR}{{Q}_{T o t a l}} and$$

$$Rt {h}_{1 , 3} = \frac{( T 1 A - T 3 A ) + ( T 1 A - T 2 A ) * T D R}{{Q}_{T o t a l}} .$$

According to various embodiments of the present disclosure, a semiconductor device includes an interconnect having a plurality of metal levels, and first and second sensor arrays. Each sensor array includes a heater at a first metal level of the plurality; a first temperature sensor at the first metal level and configured to measure temperature of the heater, and second and third temperature sensors at second and third metal levels, respectively. The second and third metal levels are on opposite sides of the first metal level. The first, second and third temperature sensors are in substantial vertical alignment with the heater. The sensor arrays can be adapted to a semiconductor device that is configured for either front side delivery or back side power delivery.

In some embodiments, which can be combined with the preceding embodiment, the semiconductor device includes a semiconductor substrate that is configured for back side power delivery. The first and second temperature sensors are on a front side of the semiconductor substrate. The third temperature sensor is on a back side of the semiconductor substrate. As such a frontside thermal resistance can be measured between the first and second temperature sensors, and a backside thermal resistance can be measured between the first and third temperature sensors. Measurements of the frontside and backside thermal resistances can be used to evaluate and compare heat dissipation in the backside versus the frontside.

In some embodiments, which can be combined with one or more of the preceding embodiments, the semiconductor device includes a semiconductor substrate. The heater and the first, second and third temperature sensors are on one side of the semiconductor substrate. That one side may be the front side or back side of the semiconductor substrate.

In some embodiments, which can be combined with the preceding embodiments, the semiconductor device further includes a processor programmed to compute thermal resistance between the second and third metal levels. As equal heating power is applied to the first and second heaters, a first set of temperatures is collected from the first, second and third temperature sensors of the first sensor array, a second set of temperatures is collected from the first, second and third temperature sensors of the second sensor array, and the thermal resistance is computed as a function of the heating power, and the first and second sets of temperatures. The measured thermal resistance can be used for thermal property monitoring and feedback for thermal design optimization.

### Example Structure for Extracting Thermal Resistance

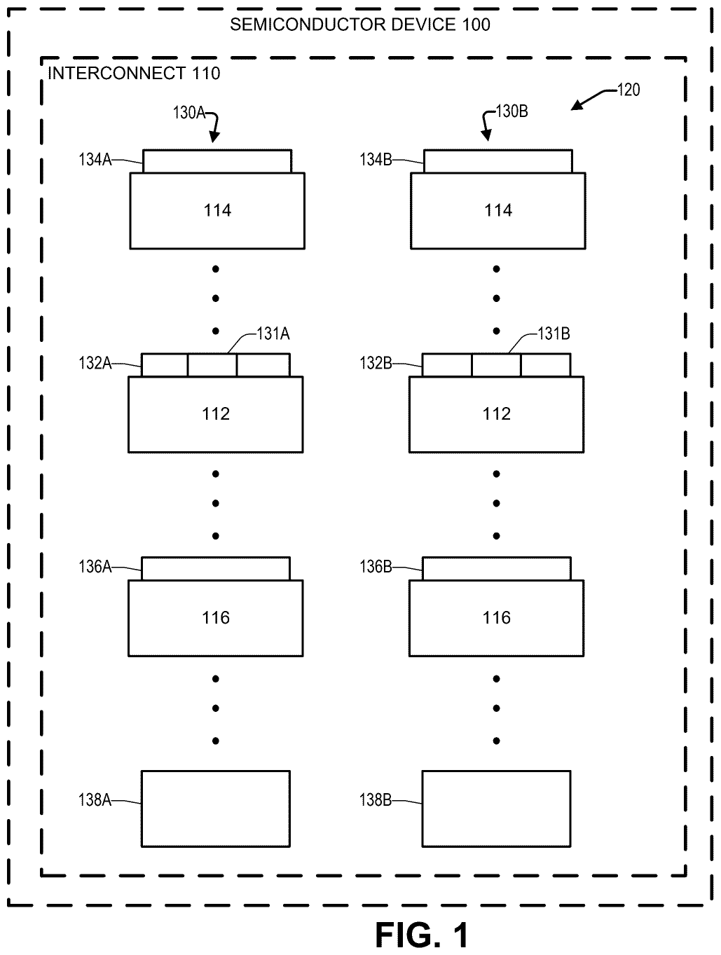

Reference now is made to FIG. 1, which illustrates an example semiconductor device 100. The semiconductor device 100 includes a semiconductor substate (not shown), an electric components layer (not shown) formed in a semiconductor surface of the semiconductor substrate, and an interconnect 110 for routing data signals, control signals, and power supply voltage signals to electrical components in the electronics component layer.

The interconnect 110 includes a first, second, and third metal levels, 112, 114 and 116. Each metal level 112, 114 and 116 includes patterned metal on a dielectric layer. The second and third metal levels 114 and 116 are on opposite sides of the first metal level 112. The terms first, second and third do not denote order, nor do these terms limit the interconnect layer 110 to three metal levels. There may be one or more additional metal levels between the first and second metal levels 112 and 114. There may be one or more additional metal levels between the first and third metal levels 112 and 116. There may be no additional metal levels between the first and second metal levels 112 and 114. There may be no additional metal levels between the first and third metal levels 112 and 116.

In some embodiments, the first, second and third metal levels 112, 114 and 116 may be on one side of the semiconductor substrate. For example, the first, second and third metal levels 112, 114 and 116 may be on a front side such that the interconnect 110 is configured for front side power delivery to the electronics component layer. In other embodiments, one of the second and third metal levels 114 and 116 may be on a back side of the semiconductor substrate, such that the interconnect 110 is configured for back side power delivery to the electronics component layer. Examples of interconnects 110 configured for front side power delivery and back side power delivery are described below.

FIG. 1 also illustrates an example structure 120 for extracting thermal resistance in the semiconductor device 100. The structure 120 includes first and second sensor arrays 130A and 130B that are horizontally spaced apart.

The first sensor array 130A includes a heater 131A at the first metal level 112. The first sensor array 130A further includes first, second and third temperature sensors 132A, 134A and 136A. The first, second and third temperature sensors 132A, 134A and 136A are in substantial vertical alignment with the heater 131A.

The first temperature sensor 132A is located at the first metal level 112 and configured to measure temperature of the heater 131A. The second temperature sensor 134A is located at the second metal level 114 and is configured to sense heat flowing above the heater 131A. The third temperature sensor 136A is located at the third metal level 116 and is configured to sense heat flowing below the heater 131A.

The first sensor array 130A also includes a dielectric region 138A in substantial vertical alignment with the heater 131A. In some embodiments, the dielectric region 138A may be above the second metal level 114. In the example of FIG. 1, the dielectric region 138A is below the third metal level 116.

The second sensor array 130B also includes a heater 131B, first, second and third temperature sensors 132B, 134B and 136B, and a dielectric region 138B. The second sensor array 130B is structurally the same (e.g., same material, thickness, thermal resistance) to the first sensor array 130A, except for the dielectric regions 138B. The dielectric region 138A of the first temperature sensor 130A has a measurably different thermal resistance than the dielectric region 138B of the second sensor array 130B. The thermal resistance may be varied by varying one or more characteristics (for example, material, structure, thickness metal fill density) of the dielectric regions 138A and 138B.

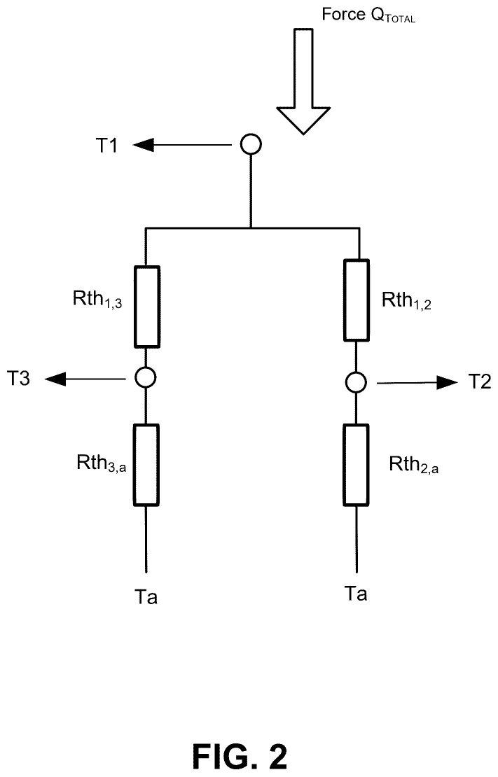

Additional reference is made to FIG. 2, which illustrates a thermal path to ambient for each of the first and second sensor arrays 130A and 130B. The double arrow represents that the total heat flow being forced through the first sensor array 130A is the same as the heat flow being forced through the second sensor array 130B.

The term Rth_{1,3} represents the thermal resistance between the first and third metal levels 112 and 116, The term Rth_{1,2} represents the thermal resistance between the first and second metal levels112 and 114. The term Rth₃ₐ represents the thermal resistance between the third metal level 116 and ambient. The term Rth_{2, a} represents the thermal resistance between the second metal level 114 and ambient. T1, T2, and T3 represent the temperatures measured at the first, second and third metal levels 112, 114, and 116, respectively.

Rth_{2,a} of the second sensor array 130B is measurably lower than Rth_{2,a} of the first sensor array 130A. Rth_{1,2} of the first sensor 130A array may be the same as Rth_{1,2} of the second sensor array 130B. Rth_{1,3} of the first sensor 130A array may be the same as Rth_{1,3} of the second sensor array 130B.

### Example Method of Extracting Thermal Resistance

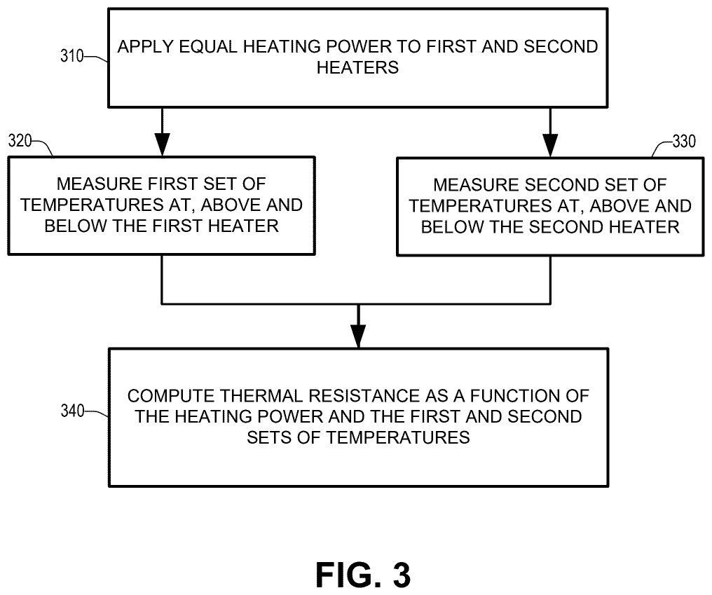

Reference is made to FIG. 3, which illustrates a method of using the structure 120 of FIG. 1 to extract thermal resistance in the semiconductor device 100. At block 310, the same heating power (Q_{Total}) is applied to the heaters 131A and 131B of the first and second sensor arrays 130A and 130B.

At block 320, a first set of temperatures is measured for the first sensor array 130A. The first set includes a first temperature (T1A) measured by the temperature sensor 132A at the first metal level 112, a second temperature (T2A) measured by the temperature sensor 134A at the second metal level 114, and a third temperature (T3A) measured by the temperature sensor 136A at the third metal level 116.

At block 330, a second set of temperatures is measured for the second sensor array 130B. The second set includes a first temperature (T1B) measured by the temperature sensor 132B at the first metal level 112, a second temperature (T2B) measured by the temperature sensor 134B at the second metal level 114, and a third temperature (T3B) measured by the temperature sensor 136B at the third metal level 116.

At block 340, the thermal resistance is computed as a function of the heating power, and the first and second sets of temperatures. In some embodiments, the thermal resistance between the first and second metal levels (Rth_{1,2}) and the thermal resistance between the first and third metal levels (Rth_{1,3}) may be computed as follows.

Let Q_{Total}=Q_{1,2}+Q_{1,3}, where Q_{1,2} is the heat flow from the first metal level to the second metal level, and Q_{1,3} is the heat flow from the first metal level to the third metal level. For the first sensor array 130A, let T1−Ta=Q_{1,3} (RthA_{1,3}+RthA_{3,a}) and T1−Ta=Q_{1,2} (RthA_{1,2}+RthA_{2,a}), where Ta represents ambient temperature. For the first sensor array 130A,

$${Q}_{Total} = \frac{( T 1 A - T 3 A )}{{RthA}_{1 , 3}} + \frac{( T 1 A - T 2 A )}{{RthA}_{1 , 2}} .$$

For the second sensor array 130B,

$${Q}_{Total} = \frac{( T 1 B - T 3 B )}{{RthB}_{1 , 3}} + \frac{( T 1 B - T 2 B )}{{RthB}_{1 , 2}} .$$

Let RthA_{1,3}=RthB_{1,3}=Rth_{1,3} and let RthA_{1,2}=RthB_{1,2}=Rth_{1,2}. Now let TDR represent a thermal dissipation ratio, where TDR=

$$\frac{{RthB}_{1 , 3}}{{RthB}_{1 , 2}} .$$

When Q_{Total} is the same for each of the first and second sensor arrays 130A and 130B, the thermal dissipation ratio may be expressed as

$$TDR = \frac{( T 1 A - T 3 A ) - ( T 1 B - T 3 B )}{( T 1 B - T 2 B ) - ( T 1 A - T 2 A )} .$$

The total heat flow (Q_{Total}) forced through the first sensor array 130A may be rewritten as

$${Q}_{Total} = \frac{( T 1 A - T 3 A )}{{Rth}_{1 , 3}} + \frac{( T 1 A - T 2 A )}{{Rth}_{1 , 2}} * T D R .$$

The thermal resistance between the first and third metal levels 112 and 116 of the first sensory array 130A may be rewritten as

$$R t {h}_{1 , 3} = \frac{( T 1 A - T 3 A ) + ( T 1 A - T 2 A ) * T D R}{{Q}_{T o t a l}} .$$

Following the same approach, the thermal resistance between the first and second metal levels 112 and 114 of the first sensor array 130A may be written as follows:

$$R t {h}_{1 , 2} = \frac{( T 1 A - T 2 A ) + ( T 1 A - T 3 A ) / TDR}{{Q}_{T o t a l}} .$$

### Variations of Structure for Extracting Thermal Resistance

In some embodiments of a structure herein, the heaters may include resistive heaters. In some embodiments of a structure herein, the heaters may include circuit heaters. In other embodiments, the heaters may include diodes, transistors, or other semiconductor structures that generate heat when a current flows through.

In some embodiments of a structure herein, the temperature sensors may be metal sensors. In general, a metal sensor exhibits a predictable change in electrical resistance with temperature. The resistance change is used to accurately measure temperature.

One example of a metal sensor is a four-point Kelvin structure. Resistance can be measured by measuring the current going through the sensor and the voltage (force) dropped across the sensor. For resistance-based temperature measurement, a four-point Kelvin sensor may be more accurate than a two-point Kelvin sensor.

In the example structure 120 of FIG. 1, the dielectric regions 138A and 138B are shown below the third metal level 116. However, a structure herein is not so limited.

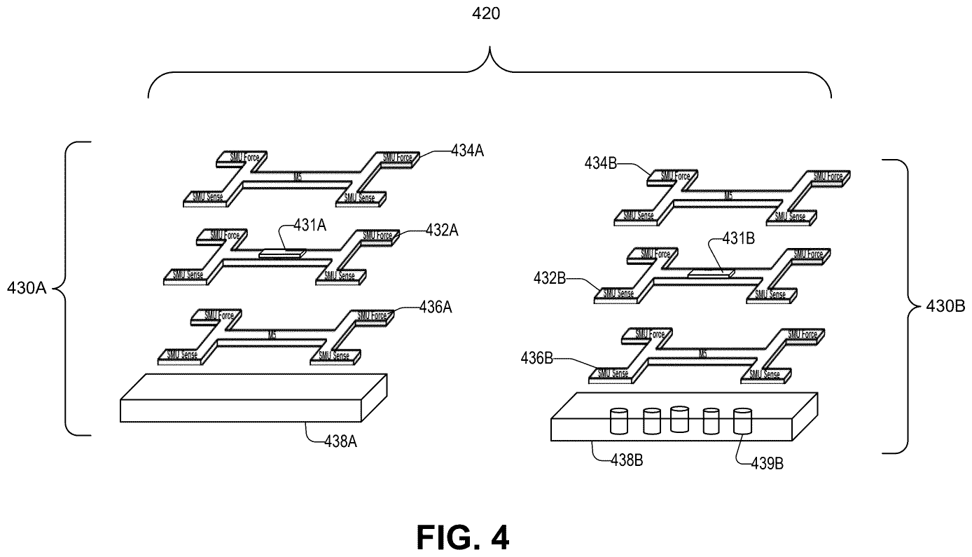

Reference is made to FIG. 4, which illustrates an example structure 420 that utilizes four-point Kelvin structures to sense temperatures. A first sensor array 430A includes a first Kelvin structure 432A for sensing temperature at a first metal level, a second Kelvin structure 434A for sensing temperature at a second metal level, and a third Kelvin structure 436A for sensing temperature at a third metal level. A second sensor array 430B includes a first Kelvin structure 432B for sensing temperature at the first metal level, a second Kelvin structure 434B for sensing temperature at the second metal level, and a third Kelvin structure 436B for sensing temperature at the third metal level.

The first Kelvin structures 432A and 432B are configured to function as heaters as well as temperature sensors. Each Kelvin structure 432A and 432B may include an additional layer 431A and 431B, respectively, that functions as a heater.

A dielectric layer is below the third Kelvin structures 436A and 436B of the first and second sensor arrays 430A and 430B, respectively. A region 438B of the dielectric layer below the third Kelvin structure 436B of the second sensor array 430B has a measurably lower thermal resistance than a region 438A below the third Kelvin structure 436A of the first sensor array 430A. The cylinders 439B in the region 438B of the second sensor array 430B represent the addition of conductive particles to lower the thermal resistance.

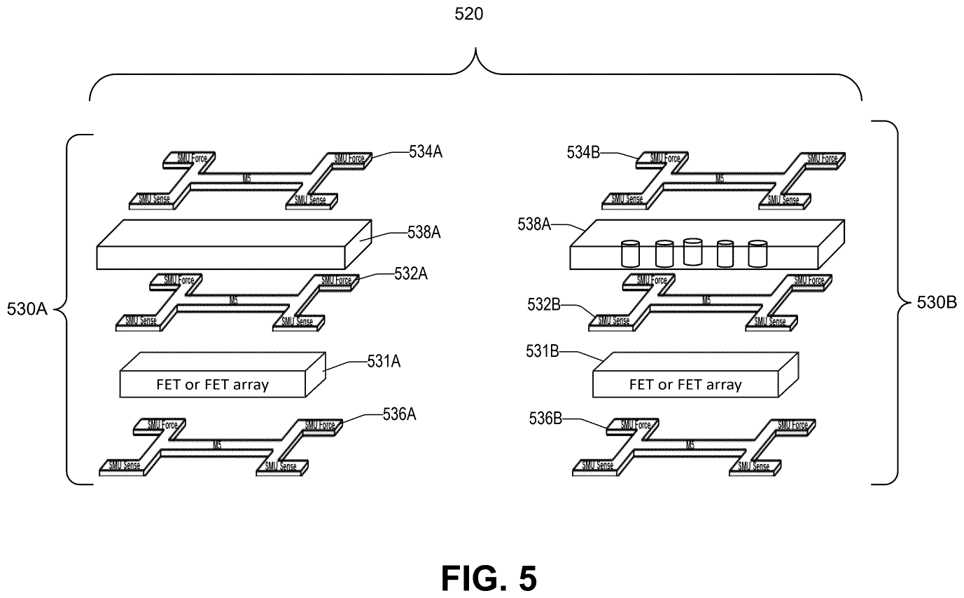

Reference is made to FIG. 5, which illustrates an example structure 520 including first and second sensor arrays 530A and 530B. The first sensor array 530A includes first, second and third Kelvin structures 532A, 534A and 536A for sensing temperature at first, second and third metal levels, respectively. The second sensor array 530B includes first, second and third Kelvin structures 532B, 534B and 536B for sensing temperature at the first, second and third metal levels, respectively.

In the structure of FIG. 5, the first Kelvin structures 532A and 532B only function as temperature sensors. Heaters 531A and 531B are implemented with FETs or FET arrays. The heaters 531A and 531B are located between the first and third metal levels.

A dielectric layer between the first and second metal levels has a region 538A within the first sensor array 530A and a region 538B of lower thermal resistance region within the second sensor array 530B. The thermal path of each sensor array 530A and 530B goes from the heater to ambient. In this example, RthA_{3,a}=RthB_{3,a}, RthA_{2,a}=RthB_{2,a}, and RthA_{1,3}=RthB_{1,3} but RthA_{1,2} and RthB_{1,2} are different due to the lower thermal resistances between the heater and the second temperature sensor.

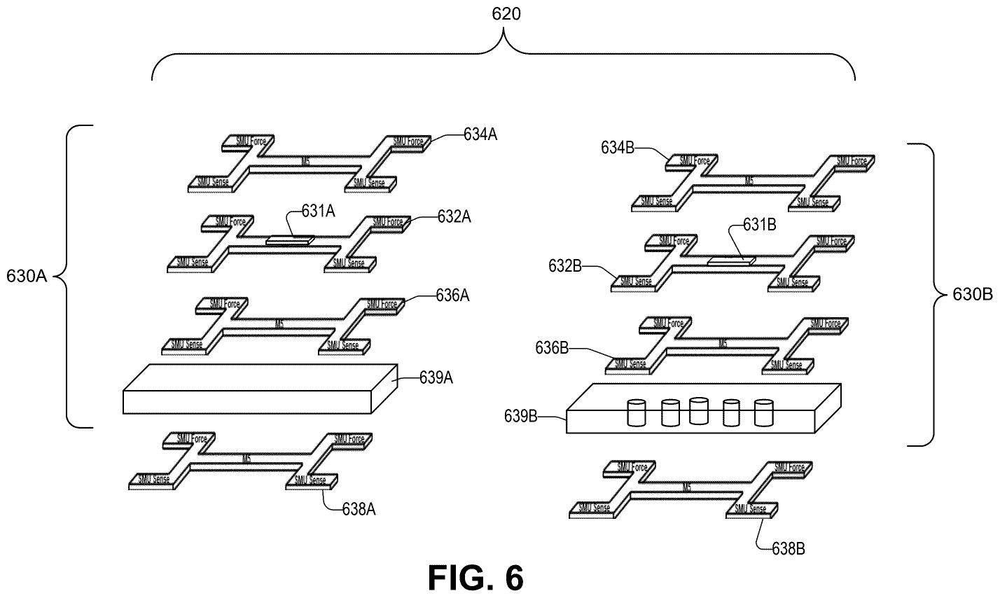

Reference is made to FIG. 6, which illustrates an example structure 620 including first and second sensor arrays 630A and 630B. The first sensor array 630A includes first, second and third Kelvin structure 632A, 634A and 636A for sensing temperature at first, second and third metal levels, respectively. The second sensor array 630B includes first, second and third Kelvin structure 632B, 634B and 636B for sensing temperature at the first, second and third metal levels, respectively.

In the structure 620 of FIG. 6, the first and second sensor arrays 630A and 630B further include fourth Kelvin structures 638A and 638B, respectively, for sensing ambient temperature. A dielectric layer has first and second regions 639A and 639B having measurably different thermal resistances. The first region 639A is between the third and fourth Kelvin structures 636A and 638A of the first sensor array 630A, and the second region 639B is between the third and fourth Kelvin structures 636B and 638B of the second sensor array 630B.

Each sensor array 630A and 630B also includes a circuit heater 631A and 631B on its respective first Kelvin structure 632A and 632B. Each circuit heater 631A and 631B may include multiple metal lines.

In the example structures above, each sensor array has a heater, temperature sensors and dielectric regions that are in vertical alignment. However, a structure herein is not so limited. In some embodiments, the alignment may be substantially horizontal.

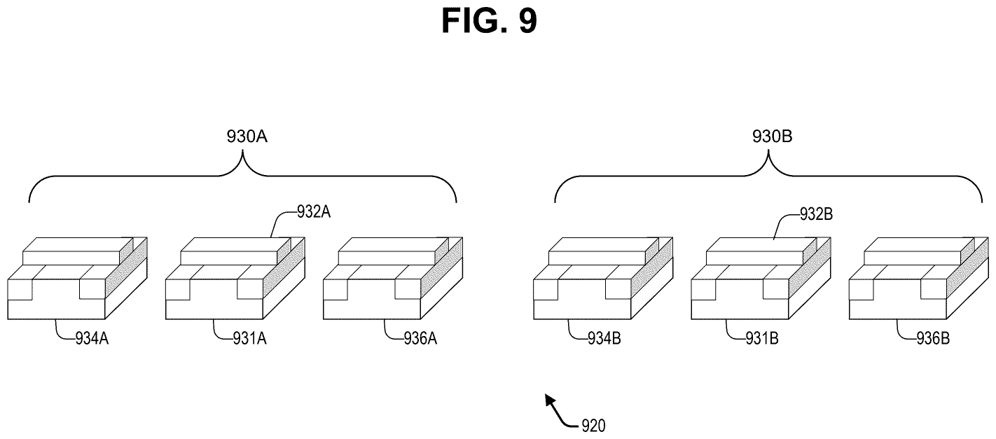

Reference is made to FIG. 9, which illustrates an example structure 920 including first and second sensor arrays 930A and 930B in substantial horizontal alignment. The first sensor array 930A includes a heater 931A and second and third temperature sensors 934A and 936A that are in substantial horizontal alignment. Similarly, the second sensor array 930B includes a heater 931B and second and third temperature sensors 934B and 936B that are in substantial horizontal alignment.

Each of the second and third temperatures sensors 934A, 934B, 936A and 936B may include a metal oxide semiconductor field effect transistor (MOSFET). Subthreshold slope, threshold voltage, or gate resistance of the MOSFETs may be used to sense the temperature.

Each heater 931A and 931B includes a MOSFET that is configured to generate heat when a current flows between drain and source. Gate resistance changes can be used to monitor heat generated by the current. Subthreshold slope and threshold voltages of these MOSFETs may be used as first temperature sensors 932A and 932B.

### Example Semiconductor Devices

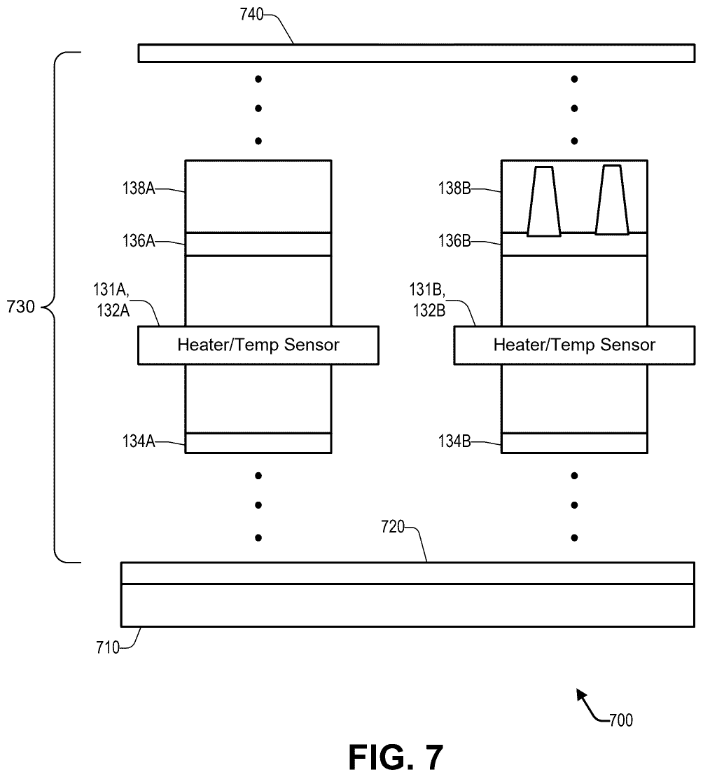

As discussed above, a semiconductor device herein is configurable for front side power delivery or back side power delivery. In this regard, reference is made to FIG. 7, which illustrates a semiconductor device 700 configured for front side power delivery. The semiconductor device 700 includes a semiconductor substrate 710 and an FEOL 720 on the front side of the semiconductor substrate 710.

An interconnect 730 is formed on the front side of the FEOL 720. Data, control and power signals are carried to the FEOL 720 by the interconnect 730.

The interconnect 730 also includes at least one structure for extracting thermal resistance. Any of the structures illustrated in FIGS. 1, 4, 5 and 6 may be used. By way of example, consider the structure 120 of FIG. 1. The second temperature sensors 134A and 134B are closest to the FEOL 720, the heater/first temperature sensors 131A, 132A, 131B and 132B are above the second temperature sensors 134A and 134B, the third temperature sensors 136A and 136B are above the first temperature sensors 132A and 132B, and the dielectric regions 138A and 138B provide a thermal path to a thermal boundary 740.

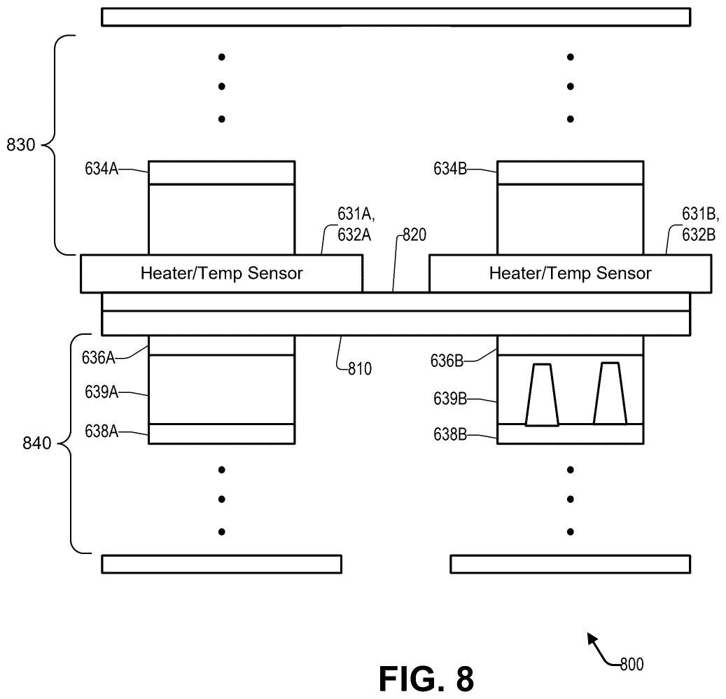

Reference is made to FIG. 8, which illustrates a semiconductor device 800 configured for back side power delivery. The semiconductor device 800 includes a semiconductor substrate 810 and an FEOL 820 on a front side of the semiconductor substrate 810.

A back side interconnect layer 840 is on a back side of the semiconductor substrate 810. The back side interconnect layer 840 routes power signals to the FEOL 820.

A front side interconnect layer 830 is on a front side of the electrical components layer. The front side interconnect layer 830 routes data and control signals to the FEOL 820.

Any of the structures illustrated in FIGS. 1, 4, 5 and 6 may be used to measure thermal resistance in the semiconductor device 800. Consider the structure of FIG. 6. The third Kelvin structures 636A and 636B are nearest the back side of the semiconductor substrate 810. The regions 639A and 639B having measurably different thermal resistances are below their respective third Kelvin structures 636A and 636B. The fourth Kelvin structures 638A and 638B are below their respective regions 639A and 639B.

The heaters/first Kelvin structures 631A/632A and 631B/632B are nearest the front side of the FEOL 820. The second Kelvin structures 634A and 634B are above their respective heaters/first Kelvin structures 631A/632A and 631B/632B.

A semiconductor device herein is not limited to a single structure for measuring thermal resistance. A semiconductor device herein may include multiple such structures at different metal levels.

A semiconductor device herein may include an on-chip core or processor that is programmed to receive the temperature measurements from the temperature sensors and compute thermal resistance between metal levels according to a method herein. In the alternative, the temperature measurements may be supplied to an external computing device, which is programmed to receive the temperature measurements and compute the thermal resistance between metal levels according to a method herein.

### Example Fabrication Method

With the foregoing description of structures and semiconductor devices herein, it may be helpful to discuss an example manufacturing process. A semiconductor device such as an SoC starts as a bare piece of high-quality, crystalline silicon. For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Fabrication of the devices discussed herein can comprise multi-step sequences of, for example, photolithographic and/or chemical processing steps that facilitate gradual creation of electronic-based systems, devices, components, and/or circuits in a semiconducting and/or a superconducting device (e.g., an integrated circuit). For instance, devices discussed herein can be fabricated on one or more substrates (e.g., a silicon (Si) substrates, and/or another substrate) by employing techniques including, but not limited to: photolithography, microlithography, nanolithography, nanoimprint lithography, photomasking techniques, patterning techniques, photoresist techniques (e.g., positive-tone photoresist, negative-tone photoresist, hybrid-tone photoresist, and/or another photoresist technique), etching techniques (e.g., reactive ion etching (RIE), dry etching, wet etching, ion beam etching, plasma etching, laser ablation, and/or another etching technique), evaporation techniques, sputtering techniques, plasma ashing techniques, thermal treatments (e.g., rapid thermal anneal, furnace anneals, thermal oxidation, and/or another thermal treatment), chemical vapor deposition (CVD), atomic layer deposition (ALD), physical vapor deposition (PVD), molecular beam epitaxy (MBE), electrochemical deposition (ECD), chemical-mechanical planarization (CMP), backgrinding techniques, and/or another technique for fabricating an integrated circuit.

A layer of transistors is made at the very top of that silicon (FEOL).

Next, the transistors are linked together with metal interconnect to form circuits with useful computing functions (BEOL). These interconnects are formed in layers called a stack, and it can take a 10-to-20-layer stack to deliver power and data to the billions of transistors on a modern chip. The temperature sensors and heaters are formed at this stage.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

The components, steps, features, objects, benefits and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

What is claimed is:

1. A structure for extracting thermal resistance in a semiconductor device, the structure comprising first and second sensor arrays, wherein each sensor array of the first and second sensor arrays comprises:
a heater;
a first temperature sensor configured to measure temperature of the heater; and
second and third temperature sensors on opposite sides of the heater;
wherein:
the heater and the temperature sensors of the first sensor array are along a first thermal path to ambient;
the heater and the temperature sensors of the second sensor array are along a second thermal path to ambient; and
the first thermal path to ambient has a measurably different thermal resistance than the second thermal path to ambient.

2. The structure of claim 1, wherein:
the semiconductor device has an interconnect;
the first, second and third temperature sensors of each sensor array are at first, second and third metal levels of the interconnect, respectively; and
for each sensor array, the first, second, and third temperature sensors are in substantial vertical alignment with the heater.

3. The structure of claim 2, wherein:
the first sensor array includes a first dielectric region along the first thermal path to ambient;
the second sensor array includes a second dielectric region along the second thermal path to ambient; and
the first dielectric region has a measurably different thermal resistance than the second dielectric region.

4. The structure of claim 2, wherein:
thermal resistance between the first and second metal levels is same for the first and second sensor arrays; and
thermal resistance between the first and third metal levels is same for the first and second sensor arrays.

5. The structure of claim 4, wherein:
each sensor array further comprises a fourth temperature sensor; and
thermal resistance between the third and fourth temperature sensors is measurably different for the first and second sensor arrays.

6. The structure of claim 2, wherein:
a thermal resistance between the first and third metal levels is same for the first and second sensor arrays; and
thermal resistance between the first and second metal levels is measurably different for the first and second sensor arrays.

7. The structure of claim 6, wherein the heater of each sensor array includes an electronic component between the first and third metal levels.

8. The structure of claim 2, wherein the first, second, and third temperature sensors of each sensor array include four-point Kelvin structures.

9. A method of extracting thermal resistance in a semiconductor device, the method comprising:
applying equal heating power to spaced-apart first and second heaters at a first level of the semiconductor device;
measuring a first set of temperatures, including a first temperature at the first heater, and second and third temperatures above and below the first heater at levels on opposite sides of the first level;
measuring a second set of temperatures, including a first temperature at the second heater, and second and third temperatures above and below the second heater at the levels on opposite sides of the first level; and
determining the thermal resistance as a function of the heating power, and the first and second sets of temperatures.

10. The method of claim 9, wherein:
heat generated by the first heater is flowed through a first dielectric region above or below the first heater;
heat generated by the second heater is flowed through a second dielectric region above or below the second heater; and
the first and second dielectric regions have measurably different thermal resistances.

11. The method of claim 10, wherein the thermal resistance is computed as a function of the heating power, a thermal dissipation ratio, temperature differences between the first and second levels, and temperature differences between the first and third levels.

12. The method of claim 11, wherein the thermal dissipation ratio (TDR) is computed as:
$$TDR = \frac{( T 1 A - T 3 A ) - ( T 1 B - T 3 B )}{( T 1 B - T 2 B ) - ( T 1 A - T 2 A )}$$
wherein:
T1A, T2A and T3A are the first, second and third measured temperatures, respectively, of the first set; and
T1B, T2B and T3B are the first, second and third measured temperatures, respectively, of the second set.

13. The method of claim 12, wherein the thermal resistance includes a thermal resistance (Rth_{1,2}) between the first and second levels and a thermal resistance (Rth_{1,3}) between the first and third levels; where
$$\begin{matrix}Rt {h}_{1 , 2} = \frac{( T 1 A - T 2 A ) + \frac{T 1 A - T 3 A}{T D R}}{{Q}_{T o t a l}} \\ Rt {h}_{1 , 3} = \frac{( T 1 A - T 3 A ) + ( T 1 A - T 2 A ) * T D R}{{Q}_{T o t a l}} .\end{matrix}$$

14. A semiconductor device, comprising:
an interconnect having a plurality of metal levels; and
first and second sensor arrays, wherein each sensor array comprises:
a heater at a first metal level of the plurality of metal levels;
a first temperature sensor at the first metal level and configured to measure a temperature of the heater; and
second and third temperature sensors at second and third metal levels, respectively;
wherein:
the second and third metal levels are on opposite sides of the first metal level; and
the first, second, and third temperature sensors are in substantial vertical alignment with the heater.

15. The semiconductor device of claim 14, wherein:
the semiconductor device includes a semiconductor substrate that is configured for back side power delivery;
the first and second temperature sensors are on a front side of the semiconductor substrate; and
the third temperature sensor is on a back side of the semiconductor substrate.

16. The semiconductor device of claim 14, wherein:
the semiconductor device includes a semiconductor substrate; and
the heater and the first, second and third temperature sensors of each sensor array are on one side of the semiconductor substrate.

17. The semiconductor device of claim 14, further comprising a processor programmed to compute thermal resistance between the second and third metal levels as equal heating power is applied to the first and second heaters, wherein computing the thermal resistance comprises:
collecting a first set of temperatures from the first, second, and third temperature sensors of the first sensor array;
collecting a second set of temperatures from the first, second and third temperature sensors of the second sensor array; and
computing the thermal resistance as a function of the heating power, and the first and second sets of temperatures.

18. The semiconductor device of claim 17, wherein the thermal resistance is computed as a function of the heating power, a thermal dissipation ratio, temperature differences between the first and second metal levels, and temperature differences between the first and third metal levels.

19. The semiconductor device of claim 18, wherein the thermal dissipation ratio (TDR) is computed as:
$$TDR = \frac{( T 1 A - T 3 A ) - ( T 1 B - T 3 B )}{( T 1 B - T 2 B ) - ( T 1 A - T 2 A )}$$
wherein:
T1A, T2A and T3A are the first, second and third temperatures, respectively, of the first set; and
T1B, T2B and T3B are the first, second and third temperatures, respectively, of the second set.

20. The semiconductor device of claim 19, wherein the thermal resistance includes a thermal resistance (Rth_{1,2}) between the first and second metal levels and a thermal resistance (Rth_{1,3}) between the first and third metal levels; where
$$\begin{matrix}Rt {h}_{1 , 2} = \frac{( T 1 A - T 2 A ) + \frac{T 1 A - T 3 A}{T D R}}{{Q}_{T o t a l}} \\ Rt {h}_{1 , 3} = \frac{( T 1 A - T 3 A ) + ( T 1 A - T 2 A ) * T D R}{{Q}_{T o t a l}} .\end{matrix}$$
